(19) United States
(12) Patent Application Publication
(10) Pub. No.: US 2025/0368802 A1
(43) Pub. Date: Dec. 4, 2025

(54) PHOTOCURABLE COMPOSITION WITH HIGH SILICON CONTENT AND HIGH STABILITY

(71) Applicant: Canon Kabushiki Kaisha, Tokyo (JP)

(72) Inventors: Fen WAN, Austin, TX (US); Caroline M. McCuistion, Austin, TX (US)

(21) Appl. No.: 18/680,236

(22) Filed: May 31, 2024

(51) Int. Cl. C08K 5/06; C08F 230/08

(52) U.S. Cl. CPC C08K 5/06; C08F 230/085

(57) ABSTRACT

A photocurable composition can comprise a polymerizable material, a non-fluorine-containing release agent, and a photoinitiator, wherein the polymerizable material may comprise at least one silicon-containing monomer having a structure of formula (1)

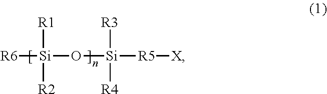

with R1, R2: —O—Si(CH₃)₃, or alkyl, or aryl, or alkylaryl; R3, R4: —O—Si(CH₃)₃, alkyl, or aryl, or alkylaryl; R5: C₁-C₅-alkyl, or aryl, or alkylaryl; R6: —R5-X, or X, or —O—Si(CH₃)₃, or alkyl, or aryl, or alkylaryl; X: acrylate or methacrylate; and n: 0-4. The amount of silicon (Si) in the photocurable composition can be at least 15 wt % based on the total weight of the polymerizable material, and the non-fluorine-containing release agent may be an acetylenic diol. The photocurable composition can have a high stability with a stability factor of at least 14.

### FIELD OF THE DISCLOSURE

The present disclosure relates to a photocurable composition, particularly to a photocurable composition for nanoimprint lithography (NIL) and inkjet adaptive planarization (IAP).

### BACKGROUND

Imprint resists having a high silicon content can be suitable to form photo-cured layers having a high etch resistance. However, photocurable compositions with silicon content greater than 15 wt % have the disadvantage of not being stable by undergoing phase separation.

There exists a need for improved photocurable compositions for IAP and NIL processing, especially for sub-20 nm CD device fabrication, wherein the photocurable compositions have a high stability, low viscosity, high curing speed, and lead to photo-cured layers with high etch resistance.

### SUMMARY

In one embodiment, a photocurable composition can comprise a polymerizable material, a non-fluorine-containing release agent, and a photoinitiator, wherein the polymerizable material can include at least one silicon-containing monomer having a structure of formula (1)

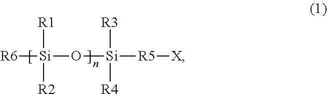

with R1, R2: —O—Si(CH₃)₃, or alkyl, or aryl, or alkylaryl; R3, R4: —O—Si(CH₃)₃, or alkyl, or aryl, or alkylaryl; R5: C₁-C₅-alkyl, or aryl, or alkylaryl; R6: —R5-X, or X, or —O—Si(CH₃)₃, or alkyl, or aryl, or alkylaryl; X: acrylate or methacrylate; and n: 0-4, an amount of silicon (Si) in the photocurable composition may be at least 15 wt % based on the total weight of the polymerizable material, and the non-fluorine-containing release agent can include an acetylenic diol.

In one aspect of the photocurable composition, the acetylenic diol can have a structure of formula (2) or formula (3):

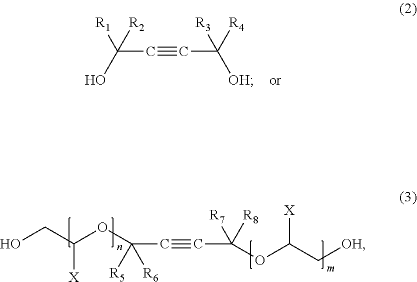

with R1, R3, R5, and R7 being the C₁-C₃ alkyl; and R2, R4, R6, and R8 being C₄-C₁₂ alkyl or isoalkyl; X being H or C₁-C₁₀ alkyl; and m, n independently being 1-40.

In a certain aspect, the acetylenic diol can have a structure of formula (4):

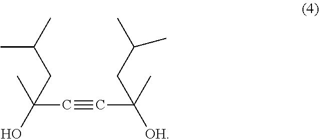 [SMILES: CC(C)CC(C)(O)C#CC(C)(O)CC(C)C]

In other certain aspects of the photocurable composition, the acetylenic diol can be an ethoxylated acetylenic diol having a structure of formula (5) or (6):

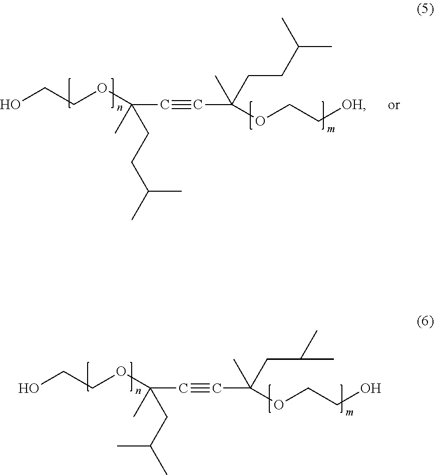

with n, m independently being 1-40.

In one aspect of the photocurable composition, the amount of Si can be at least 20 wt % based on the total weight of the photocurable composition. In a particular aspect, the amount of Si can be at least 25 wt % based on the total weight of the photocurable composition.

In one embodiment of the photocurable composition, the molecular weight of the silicon-containing monomer can be at least 100 g/mol and not greater than 800 g/mol.

In another embodiment of the photocurable composition, the amount of the at least one silicon-containing monomer can be at least 45 wt % based on the total weight of the polymerizable material.

In one aspect, the photocurable composition can comprise at least one further release agent which is not an acetylenic diol.

In a further embodiment, the viscosity of the photocurable composition may be not greater than 30 mPa·s.

In one embodiment of the photocurable composition, the amount of the polymerizable material can be at least 90 wt % based on the total weight of the photocurable composition.

In one aspect, the at least one silicon-containing monomer of the photocurable composition can include at least two different silicon-containing monomers.

In certain aspects of the photocurable composition, the at least one silicon-containing monomer can be selected from the group of:
methacryloxymethyltris(trimethylsiloxane)silane (SiM1),
1,3-bis(3-methacryloxypropyl)tetrakis(trimethylsiloxy)disiloxane (SiM2)
3-acryloxypropyl-tris(trimethylsiloxy)silane (SiM3),
(methacryloxymethyl)bis(trimethylsiloxy)methylsilane (SiM4),
3-methacryloxypropylbis(trimethylsiloxy)methylsilane (SiM5),
(3-acryloxypropyl)methylbis(trimethylsiloxy)silane (SiM6),
methacryloxypropyltris(trimethylsiloxy)silane (SiM7),
acryloxymethyltrimethylsilane (SiM8),
acryloxymethyltris(trimethylsiloxy)silane (SiM9),
1,3-bis[(acryloxymethyl)phenethyl]tetramethyldisiloxane (SiM10),
methacryloxypropyl terminated polydimethylsiloxane (SiM11),
   or any combination thereof.

In another aspect of the photocurable composition, the amount of the non-fluorine-containing surfactant can be at least 2 wt %.

In one embodiment, a stability factor (SF) of the photocurable composition can be at least 14, the stability factor being defined as the amount of days under room temperature wherein the photocurable composition does not show phase separation.

In one aspect, the polymerizable material of the photocurable composition can further comprise at least one polymerizable monomer not containing silicon. In a certain aspect, the polymerizable monomer not containing silicon can include an acrylate monomer. In a particular certain aspect, the amount of the acrylate monomer can be at least 20 wt %.

In another embodiment, a laminate can comprise a substrate and a photo-cured layer overlying the substrate, wherein the photo-cured layer can be formed from the above-described photocurable composition.

In one embodiment, a method of forming a photo-cured layer on a substrate can comprise: applying a layer of a photocurable composition on the substrate, wherein the photocurable composition comprises a polymerizable material, a non-fluorine-containing release-agent, and at least one photoinitiator, wherein the polymerizable material comprises at least one silicon-containing monomer having a structure of formula (1):

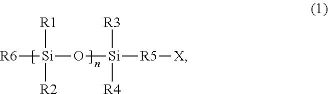

with R1, R2: —O—Si(CH₃)₃, or alkyl, or aryl, or alkylaryl; R3, R4: —O—Si(CH₃)₃, or alkyl, or aryl, or alkylaryl; R5: C₁-C₅-alkyl, aryl, alkylaryl; R6: —R5-X, or X, or —O—Si(CH₃)₃, or alkyl, or aryl, or alkylaryl; X: acrylate or methacrylate; n: 0-4, and wherein an amount of silicon (Si) in the photocurable composition is at least 15 wt % based on the total weight of the polymerizable material, and the non-fluorine-containing release agent includes an acetylenic diol; bringing the photocurable composition into contact with a template or a superstrate; irradiating the photocurable composition with light to form a photo-cured layer; and removing the template or the superstrate from the photo-cured layer.

In another embodiment, a method of manufacturing an article can comprise: applying a layer of a photocurable composition on a substrate, wherein the photocurable composition comprises a polymerizable material, a non-fluorine-containing release-agent, and at least one photoinitiator, wherein the polymerizable material comprises at least one silicon-containing monomer having a structure of formula (1):

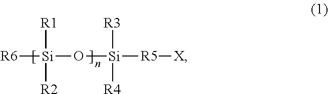

with R1, R2: —O—Si(CH₃)₃, or alkyl, or aryl, or alkylaryl; R3, R4: —O—Si(CH₃)₃, or alkyl, or aryl, or alkylaryl; R5: C₁-C₅-alkyl, aryl, alkylaryl; R6: —R5-X, or X, or —O—Si(CH₃)₃, or alkyl, or aryl, or alkylaryl; X: acrylate or methacrylate; n: 0-4, and wherein an amount of silicon (Si) in the photocurable composition is at least 15 wt % based on the total weight of the polymerizable material, and the non-fluorine-containing release agent includes an acetylenic diol; bringing the photocurable composition into contact with a template or a superstrate; irradiating the photocurable composition with light to form a photo-cured layer; removing the template or the superstrate from the photo-cured layer; forming a pattern on the substrate; processing the substrate on which the pattern has been formed in the forming; and manufacturing the article from the substrate processed in the processing.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a polymerizable material, a non-fluorine-containing release agent, and a photoinitiator, wherein the polymerizable material comprises at least one silicon-containing monomer having a structure of formula (1):

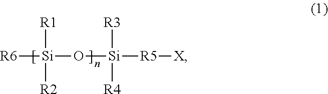

with R1, R2: —O—Si(CH₃)₃, or alkyl, or aryl, or alkylaryl; R3, R4: —O—Si(CH₃)₃, or alkyl, or aryl, or alkylaryl; R5: C₁-C₅-alkyl, or aryl, or alkylaryl; R6: —R5-X, or X, or —O—Si(CH₃)₃, or alkyl, or aryl, or alkylaryl; X: acrylate or methacrylate; and n: 0-4. The amount of silicon (Si) in the photocurable composition can be at least 15 wt % based on the total weight of the polymerizable material, and the non-fluorine-containing release agent can include an acetylenic diol.

As used herein, if not indicated otherwise, the expression “silicon-containing monomer” refers to a monomer falling under the structure of formula (1). Although formula (1) has repeating units, it is called herein “monomer” as long the molecular weight in less than 800 g/mol.

It has been surprisingly found that photocurable compositions with a silicon content of greater than 15 wt % can be prepared with high stability if an acetylenic diol is included as release agent. The photocurable compositions can be suitable, for example, for mask replication processes having a CD of less than 19 nm.

In one aspect, the acetylenic diol can be an ethoxylated acetylenic diol.

In another aspect, the acetylenic diol can have a structure of formula (2) or formula (3):

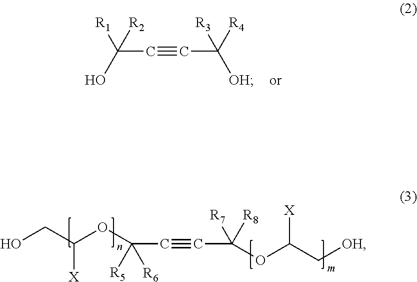

with R1, R3, R5, and R7 being C₁-C₃ alkyl; and R2, R4, R6, and R8 being C₄-C₁₂ alkyl or isoalkyl, X being H or C₁-C₁₀ alkyl, and m, n being 1-40.

In particular aspects, the acetylenic diol can have a structure of formula (4), (5), or (6).

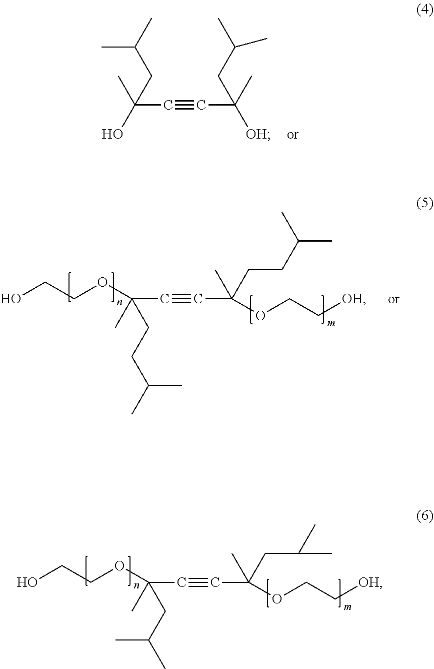

wherein n and m may be the same or different and an integer between 1-40, particularly between 1-20.

In certain aspects, the amount of silicon in the photocurable composition can be at least 16 wt % based on the total weight of the polymerizable material, such as at least 17 wt %, at least 18 wt %, at least 19 wt %, at least 20 wt %, at least 23 wt %, at least 25 wt %, or at least 28 wt %. In other aspects, the amount of silicon in the photocurable composition may be not greater than 33 wt %, or not greater than 30 wt %, or not greater than 28 wt %, or not greater than 26 wt %.

In certain aspects, the molecular weight of the silicon-containing monomer of the polymerizable material can be at least 100 g/mol, or at least 200 g/mol, or at least 300 g/mol, or at least 400 g/mol. In other aspects, the molecular weight of the silicon-containing monomer may be not greater than 800 g/mol, or not be greater than 700 g/mol, or not greater than 600 g/mol, or not greater than 500 g/mol, or not greater than 400 g/mol.

In a further aspect, the amount of the at least one silicon-containing monomer can be at least 60 wt % based on the total weight of the polymerizable material, such as at least 65 wt %, or at least 70 wt %, or at least 80 wt %, or at least 90 wt %, or at least 95 wt %, or 100 wt %. In another aspect, the amount of the silicon-containing monomer may be not greater than 99 wt % based on the total weight of the polymerizable material, or not greater than 95 wt %, or not greater than 90 wt %, or not greater than 85 wt %. In a particular aspect the amount of the silicon-containing monomer can be at least 60 wt % and not greater than 85 wt % based on the total weight of the polymerizable material.

Non-limiting examples of polymerizable monomers falling under the structure of formula (1) of the silicon-containing monomer can be:
methacryloxymethyltris(trimethylsiloxane)silane (SiM1):

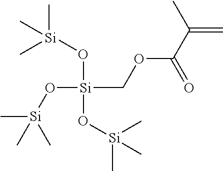 [SMILES: C=C(C)C(=O)OC[Si](O[Si](C)(C)C)(O[Si](C)(C)C)O[Si](C)(C)C]

1,3-bis(3-methacryloxypropyl)tetrakis(trimethylsiloxy)disiloxane (SiM2):

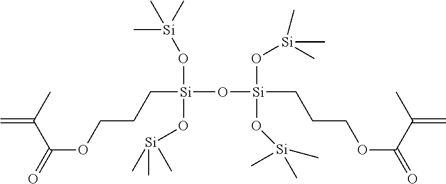 [SMILES: C=C(C)C(=O)OCCC[Si](O[Si](C)(C)C)(O[Si](C)(C)C)O[Si](CCCOC(=O)C(=C)C)(O[Si](C)(C)C)O[Si](C)(C)C]

3-acryloxypropyltris(trimethylsiloxy)silane (SiM3):

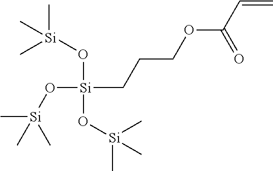 [SMILES: C=CC(=O)OCCC[Si](O[Si](C)(C)C)(O[Si](C)(C)C)O[Si](C)(C)C]

(methacryloxymethyl)bis(trimethylsiloxy)methylsilane (SiM4):

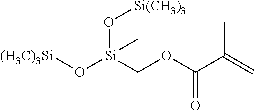

3-methacryloxypropylbis(trimethylsiloxy)methylsilane (SiM5):

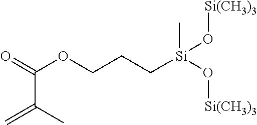

(3-acryloxypropyl)methylbis(trimethylsiloxy)silane (SiM6):

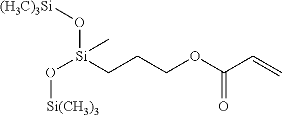

methacryloxypropyltris(trimethylsiloxy)silane (SiM7):

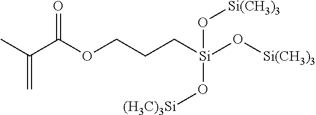

acryloxymethyltrimethylsilane (SiM8):

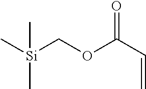

acryloxymethyltris(trimethylsiloxy)silane (SiM9):

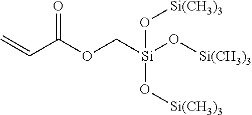

1,3-bis[(acryloxymethyl)phenethyl]tetramethyldisiloxane (SiM10):

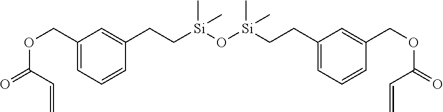 [SMILES: C=CC(=O)OCc1cccc(CC[Si](C)(C)O[Si](C)(C)CCc2cccc(COC(=O)C=C)c2)c1]

methacryloxypropyl terminated polydimethylsiloxane (SiM11):

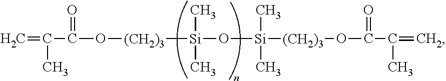

with n being 1-4.

The photocurable composition of the present disclosure can be designed of having a low viscosity before curing. In one embodiment, the viscosity of the curable composition can be not greater than 30 mPa·s, or not greater than 25 mPa·s, or not greater than 20 mPa·s, or not greater than 15 mPa·s, or not greater than 10 mPa·s. In another certain embodiment, the viscosity may be at least 3 mPa·s, or at least 5 mPa·s. In a particularly preferred aspect, the photocurable composition can have a viscosity from 5 mPa·s to not greater than 20 mPa·s. As used herein, all viscosity values relate to viscosities measured at a temperature of 23° C. with the Brookfield method using a Brookfield Viscometer.

In one embodiment, the polymerizable material of photocurable composition can further include at least one polymerizable monomer not containing silicon, such as one or more mono-functional and/or one or more multi-functional polymerizable monomers.

In one aspect, the polymerizable monomer not containing silicon can include an acrylate monomer. As used herein the term acrylate monomer relates to both unsubstituted and alkyl-substituted acrylates, for example, methacrylate. Non-limiting examples of acrylate monomers can be benzylacrylate (BA), isobornyl acrylate (IBXA), 1,5-pentanediol diacrylate (MPDA), dihydrodicyclopentadienyl acrylate (DCPA), tricyclodecane dimethanol diacrylate (A-DCP), phenyl ethanediol diacrylate) (PHEDA), bisphenol A dimethacrylate, m-xylylene diacrylate (mxDA), neopentyl glycol diacrylate, or any combination thereof.

In a further aspect, the amount of the at least one monomer not including silicon can be at least 5 wt % based on the total weight of the polymerizable material, or at least 10 wt %, or at least 15 wt %, or at least 20 wt %, or at least 25 wt %. In another aspect, the amount of monomer not including silicon may be not greater than 40 wt % based on the total weight of the polymerizable material, or not greater than 35 wt %, or not greater than 30 wt %, or not greater than 25 wt %, or not greater than 20 wt %.

The amount of polymerizable material in the photocurable composition can be at least 60 wt % based on the total weight of the photocurable composition, such as at least 70 wt %, at least 80 wt %, or at least 85 wt %, or at least 90 wt %, or at least 95 wt %. In another aspect, the amount of polymerizable material may be not greater than 99 wt %, such as not greater than 97 wt %, not greater than 95 wt %, not greater than 90 wt %, not greater than 85 wt %, or not greater than 80 wt %, or not greater than 70 wt %. The amount of the polymerizable material can be a value between any of the minimum and maximum values noted above. In a particular aspect, the amount of the polymerizable material can be at least 70 wt % and not greater than 98 wt %.

In a further embodiment, the photocurable composition can further comprise at least one second release agent not being an acetylenic diol (while the acetylenic diol is being called herein also the “first release agent”).

In one aspect, the second release agent can be a nonionic ethoxylated fluorosurfactant. Non-limiting examples of ethoxylated fluorosurfactants can be the structures of formula (7), (8), and (9):

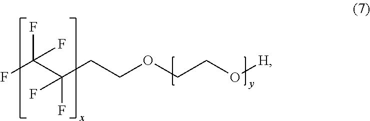

with x being 2-8, and y being 2-40;

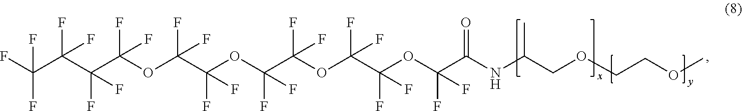

with x being 5-15, and y being 20-40;

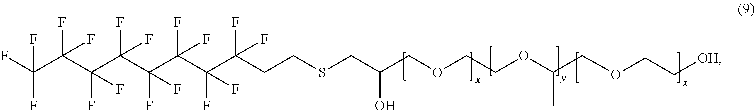

with x being 2-30, and y being 15-40.

In yet a further aspect, the second release agent can be an ethoxylated fluorine-free surfactant. A non-limiting example of an ethoxylated fluorine-free surfactant can be the structure of formula (10):

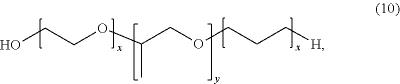

with x being 5-15, and y being 10-40.

In another aspect, the second release agent can be surfactant containing fluorine and silicon. Non-limiting examples can be the surfactants shown in formulas (11) and (12).

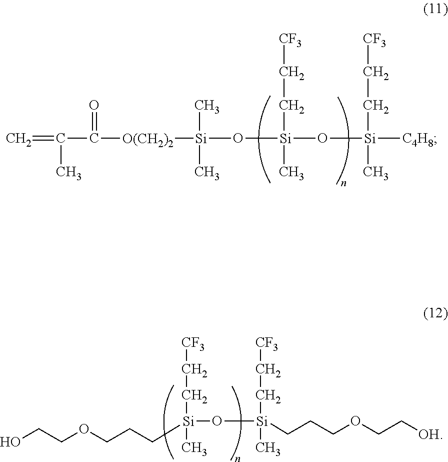

In yet a further aspect, the second release agent can be a polymer have a molecular weight between 280 and 26000 g/mol and comprise silicon and fluorine, herein called an Si/F release agent. Non-limiting examples of Si/F release agents can be polymers having the structures of formulas (13) to (17).

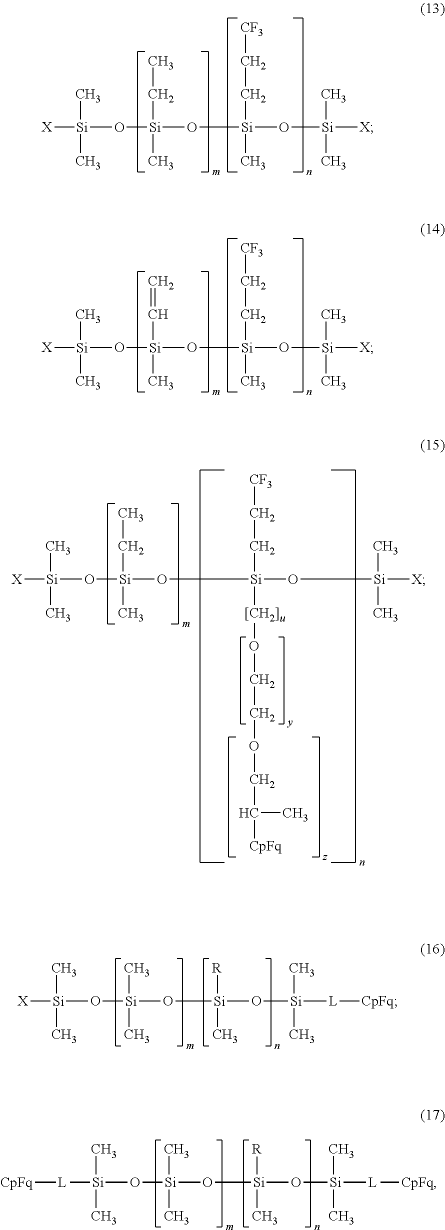

wherein
X can be C₁-C₇ alkyl, or —CH═CH₂; m can be 0 to 80, n can be 1 to 80; u can be 1 to 6, y and z may be 0 to 40; p can be 1 to 6, q can be 3 to 13, L can be O, N, S, or C₁-C₆ alkyl, R can be O, N, S, or an organic substitute group with at least one carbon.

In a particular aspect, the second release agent can adjust the contact angle of the photocurable composition to a primed template and a surface-coated substrate, such that the contact angle to the template (CA_{T}) is greater than the contact angle to the substrate (CA_{S}). As used herein, the term “primed template” means a template (e.g., a quartz slide) primed with the photocurable composition before testing the contact angle, while the surface-coated substrate is a silicon substrate coated with an adhesion layer containing.

In a non-limiting example the adhesion layer coating can be a combination of Isorad 501 with hexamethoxymethylmelamine. The structure of Isorad 501 is shown in formula (18):

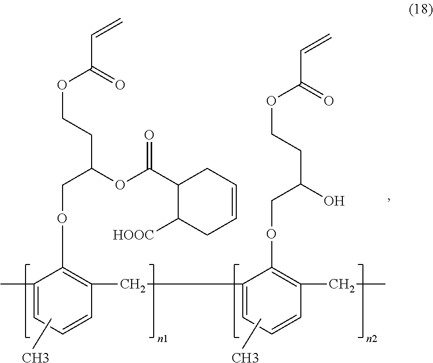

with n₁ and n₂ being 1 to 12.

In one aspect, both the CA_{T} and CA_{S} may be not greater than 15 degrees, such as not greater than 12 degrees, or not greater than 10 degrees, or not greater than 8 degree, or not greater than 6 degrees. In another aspect, CA_{T} and CA_{S} can be at least 1 degree, or at least 2 degrees, or at least 3 degrees.

In a particular aspect, the contact angle to the template can be greater than the contact angle to the substrate (CAT>CAS), wherein the difference in the contact angle (Δ CA) may be at least 0.1 degrees, or at least 0.2 degrees, or at least 0.3 degrees, or at least 0.5 degrees, or at least 1 degree, or at least 2 degrees, or at least 3 degrees. In another aspect, Δ CA may be not greater than 6 degrees, or not greater than 5 degrees, or not greater than 3 degrees, or not greater than 1 degree.

In one aspect, the amount of the second release agent can be at least 0.1 wt % based on the total weight of the photocurable composition, or at least 0.2 wt %, or at least 0.3 wt %, or at least 0.5 wt %, or at least 0.7 wt %, or at least 1 wt %, or at least 1.5 wt %, or at least 2 wt %. In another aspect, the amount of the second release agent may be not greater than 10 wt %, or not greater than 5 wt %, or not greater than 2 wt %, or not greater than 1 wt %, or not greater than 0.5 wt %.

In a certain aspect, a weight percent ratio of the first release agent (acetylenic diol) to the second release agent may be from 10:1 to 1:1, particularly from 10:1 to 3:1.

In one embodiment, the photocurable composition of the present disclosure can be essentially free of a solvent. As used herein, if not indicated otherwise, the term solvent relates to a compound which can dissolve or disperse the polymerizable monomers but does not itself polymerize during the photo-curing of the photocurable composition. The term “essentially free of a solvent” means herein an amount of solvent being not greater than 5 wt % based on the total weight of the photocurable composition. In a certain particular aspect, the amount of the solvent can be not greater than 3 wt %, not greater than 2 wt %, not greater than 1 wt % based on the total weight or the photocurable composition, or the photocurable composition can be free of a solvent, except for unavoidable impurities.

In another particular aspect, the photocurable composition can include a solvent in an amount of at least 5 wt % based on the total weight of the photocurable composition, or at least 8 wt %, at least 10 wt %, at least 15 wt %, or at least 20 wt %. In another aspect the amount of solvent may be not greater than 30 wt %, or not greater than 20 wt %, or not greater than 15 wt %, or not greater than 10 wt %, or not greater than 5 wt %, or not greater than 3 wt % based on the total weight of the photocurable composition.

In order to initiate the photo-curing of the composition if exposed to light, one or more photoinitiators can be included in the photocurable composition. In a certain aspect, the curing can be also conducted by a combination of light and heat curing.

The photocurable composition can further contain one or more optional additives. Non-limiting examples of optional additives can be stabilizers, dispersants, solvents, surfactants, inhibitors or any combination thereof.

In another aspect, the photocurable composition of the present disclosure can be essentially free of particles, for example pigment particles. As used herein, being essentially free of particles means that the curable composition contains not more than 50 particles per ml having a size of at least 200 nm, or not more than 50 particles per ml having a size of at least 150 nm, or not more than 50 particles per ml having a size of at least 100 nm, or not more than 50 particles per ml having a size of at least 50 nm, or not more than 50 particles having a size of at least 20 nm, or not more than 50 particles per ml having a size of at least 15 nm.

In yet a further embodiment, the curable composition of the present disclosure may not include epoxide-group containing monomers, or epoxy-group containing oligomers, or acrylamides, or a polyurethane.

The photocurable composition of the present disclosure can be adapted for use in inkjet adaptive planarization (IAP) or in nanoimprint lithography (NIL).

A surprising advantage of the photocurable composition of the present disclosure is that it can have a high stability. In one embodiment, the stability factor (SF) of the photocurable composition can be at least 14, wherein the stability factor is defined as the amount of days under room temperature wherein the photocurable composition does not show a phase separation. In certain aspects, the stability factor can be at least 20, or at least 30, or at least 50. As used herein, “phase separation” means that the photocurable composition divides into two separate phases or becomes cloudy (turbid). To identify phase separation, the light beam from a flash light was radiated through a glass vial containing the photocurable composition. If the light beam can pass the glass bottle without light scattering, this is used as indication for no phase separation, while phase separation is identified if the light beam of the flash light becomes scattered according to the Tyndall effect. More obvious indications for phase separation (instability of the photocurable composition), which do not need the test with the light beam, are the observation of solid precipitated particles on the bottom of the glass vial, or if two liquid layers have been formed.

In one embodiment, the photocurable composition can be applied on a substrate to form a photo-cured layer. As used herein, the combination of substrate and photo-cured layer overlying the substrate is called a laminate.

The present disclosure is further directed to a method of forming a photo-cured layer. The method can comprise applying a layer of the photocurable composition described above on the surface of a substrate, bringing the photocurable composition into contact with a template or superstrate; irradiating the photocurable composition with light to form a photo-cured layer; and removing the template or the superstrate from the photo-cured layer.

The substrate and the solidified layer may be subjected to additional processing, for example, an etching process, to transfer an image into the substrate that corresponds to the pattern in one or both of the solidified layer and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like.

The photo-cured layer may be further used as an interlayer insulating film of a semiconductor device, such as LSI, system LSI, DRAM, SDRAM, RDRAM, or D-RDRAM, or as a resist film used in a semiconductor manufacturing process.

### EXAMPLES

The following non-limiting examples illustrate the concepts as described herein.

### Example 1

Photocurable compositions were prepared with the aim of obtaining photocurable compositions having a high silicon content (at least 15 wt % Si-content) and being clear and stable solutions in the presence of a release agent (surfactant). As used herein, a photocurable composition was considered being a stable solution when all ingredients are dissolved to form a clear solution and no phase separation or cloudiness is observed after standing at room temperature for 14 days.

For preparing of the photocurable compositions, the following ingredients have been used:

### a) Silicon-Containing Polymerizable Monomers:

methacryloxymethyltris(trimethylsiloxane)silane (SiM1);
1,3-bis(3-methacryloxypropyl)tetrakis(trimethylsiloxy)disiloxane (SiM2);
3-acryloxypropyltris(trimethylsiloxy)silane (SiM3);
methacryloxypropyltris(trimethylsiloxy)silane (SiM7);
1,3-bis[(acryloxymethyl)phenethyl]tetramethyldisiloxane (SiM10); and
methacryloxypropyl terminated polydimethylsiloxane (SiM11).

### b) Polymerizable Monomers not Containing Silicon:

isobornyl acrylate (IBXA), benzyl acrylate (BA), dihydrodicyclopentadienyl acrylate (DCPA), m-xylylene diacrylate (mxDA), tricyclodecane dimethanol diacrylate (A-DCP), dipentaerythritol penta/hexa acrylate (DPHPA), and 1-phenyl-1,2-ethanediyl ester (PHEDA), and 3-methyl 1,5-pentanediol diacrylate (MPDA).

### c) Release Agents:

D810 (Dynol™ 810) from Air Products, an ethoxylated acetylenic diol having the structure shown in formula (5), with n and m being 2 to 3;
D604 (Dynol™ 604) from Air Products, an ethoxylated acetylenic diol having the structure shown in formula (5), with n and m being 4;
S554 from Chemguard Inc, a fluorine-containing surfactant having the structure shown in formula (7), with x=6, y<10, and a molecular weight of 750 g/mol;
FS2000M1 from Wonda Science, a fluorine-containing surfactant having a structure shown in formula (9), with x and y being 9 and 21, respectively;
FS2000M2 from Wonda Science, a fluorine-free surfactant having a structure shown in formula (10), with x=9 and y=21;
MFR-M15 from Gelest, a fluorine- and silicon-containing surfactant; having a structure shown in formula (11), with n being 15-40.
FMS C32 from Gelest, a fluorine- and silicon-containing surfactant; having a structure shown in formula (12), with n being 15 to 40.

### d) Photoinitiators:

As photoinitiators were used Irgacure TPO, Irgacure 4265, and Irgacure 907, all from BASF.

A first series of comparative photocurable compositions is summarized in Tables 1 and 2. These samples demonstrate that the inclusion of traditional release agents typically used for resists in NIL or AIP processing could only assist in making stable and clear solutions up to an Si-content of about 14.5 wt %. However, it was not possible, also with varying the types of polymerizable monomers, to obtain stable solutions at silicon-contents greater than 15 wt %.

Tables 3 and 4 summarize photocurable compositions representative to the present invention. These compositions all contain as release agent an acetylenic diol. It was surprisingly observed that when using an acetylenic diol as release agent clear and stable solutions of the photocurable compositions can be obtained up to a silicon content of about 30 wt % based on the total weight of the photocurable composition.

In Tables 1-4, the term “solubility” expresses the stability of the photocurable compositions, with “Y” meaning that a clear photocurable composition was formed, which maintained the clarity at least for 14 days; and “N” meaning that the photocurable composition was not a clear solution or underwent phase separation within 14 days.

TABLE 1

| Ingred. | C1 | C2 | C3 | C4 | C5 | C6 | C7 | C8 | C9 | C10 | C11 |
|---|---|---|---|---|---|---|---|---|---|---|---|
| SiM1 | | | 50 | 50 | 50 | 50 | 50 | 50 | 50 | 50 | 50 |
| SiM2 | 50 | | | | | | | | 25 | 25 | 25 |
| SiM3 | | 50 | | | | | | | | | |
| SiM7 | | | | | | | | | | | |
| SiM10 | | | | | | | | | | | |
| SiM11 | | | | | | | | | | | |
| BA | 25 | 25 | 25 | | | | 25 | 10 | | | |
| DCPA | 25 | | | 25 | 25 | 25 | | | | | |
| A-DCP | | 25 | 25 | | | | 25 | | | | |
| PHEDA | | | | 25 | 25 | 25 | | 25 | 25 | 25 | 25 |
| DPHPA | | | | | | | | 15 | | | |
| Irgacure | 1 | 1 | 1 | | | | 1 | 1 | | | |
| TPO | | | | | | | | | | | |
| Irgacure | 3 | 3 | 3 | | | | 3 | 3 | | | |
| 4265 | | | | | | | | | | | |
| Irgacure | | | | 2 | 2 | 2 | | | 1.5 | 1.5 | 1.5 |
| 907 | | | | | | | | | | | |
| FSKM1 | 2 | 2 | 2 | 0.5 | | | | | | 0.5 | |
| FSKM2 | 2 | 2 | 2 | 3 | 3 | 3 | 3 | 3 | 3 | 3 | 2 |
| MFR- | | | | | 0.5 | | | | | | |
| M15 | | | | | | | | | | | |
| FMS | | | | | | | | | | | |
| C32 | | | | | | | | | | | |
| S554 | | | | | | 0.5 | | | 1 | | |
| C10GM2070 | | | | | | | | | | | |
| FC4430 | | | | | | | | | | | |
| Si [%] | 12.3 | 13.7 | 14.2 | 14.2 | 14.2 | 14.2 | 14.2 | 14.2 | 20.3 | 20.3 | 20.3 |
| Solub. | Y | Y | Y | Y | Y | Y | Y | Y | N | N | N |

TABLE 2

| Ingred. | C12 | C13 | C14 | C15 | C16 | SR17 | C18 | C19 | C20 | C21 | C22 |
|---|---|---|---|---|---|---|---|---|---|---|---|
| SiM1 | 50 | 50 | 50 | 75 | 75 | 75 | | | 50 | 50 | 50 |
| SiM2 | 25 | 25 | 25 | | | | | 50 | 50 | 50 | 50 |
| SiM3 | | | | | | | | | | | |
| SiM7 | | | | | | | 50 | 50 | | | |
| SiM10 | | | | | | | | | | | |
| SiM11 | | | | | | | 50 | | | | |
| BA | | | | | | | | | | | |
| DCPA | 25 | 25 | 25 | | | | | | | | |
| A-DCP | | | | | | | | | | | |
| PHEDA | | | | 25 | 25 | 25 | | | | | |
| DPHPA | | | | | | | | | | | |
| Irgacure | | | | | | | | | | | |
| TPO | | | | | | | | | | | |
| Irgacure | | | | | | | | | | | |
| 4265 | | | | | | | | | | | |
| Irgacure | 1.5 | 1.5 | 1.5 | 2 | 2 | 2 | 2 | | 2 | 2 | 2 |
| 907 | | | | | | | | | | | |
| FSKM1 | 0.5 | | | 0.5 | | | | | | | |
| FSKM2 | 3 | 3 | 2 | | | | 3 | 3 | 3 | 1 | 1 |
| MFR- | | | | | | | | | | | |
| M15 | | | | | | | | | | | |
| FMS C32 | | | | | 3 | | | | | | |
| S554 | | | | | | | | | | | |
| C10GM2070 | | | | | | | | | | | 0.5 |
| FC4430 | | | | | | | | | | 0.5 | |
| Si [%] | 20.3 | 20.3 | 20.3 | 21.3 | 21.3 | 21.3 | 25.5 | 26.5 | 26.5 | 26.5 | 26.5 |
| Solub. | N | N | N | N | N | N | N | N | N | N | N |

TABLE 3

| Ingredient | S1 | S2 | S3 | S4 | S5 | S6 | S7 | S8 |
|---|---|---|---|---|---|---|---|---|
| SiM1 | 50 | | 50 | | | | 50 | 50 |
| SiM2 | | | 50 | 20 | 35 | 50 | | |
| SiM3 | | | | | | | | |
| SiM7 | | 50 | | 80 | 65 | 50 | | |
| SiM10 | | | | | | | | 50 |
| SiM11 | 50 | 50 | | | | | 50 | |
| BA | | | | | | | | |
| A-DCP | | | | | | | | |
| PHEDA | | | | | | | | |
| DPHPA | | | | | | | | |
| Irgacure 907 | 2 | 2 | 2 | 2 | 2 | 2 | 2 | 2 |
| D810 | 3 | 3 | 3 | 3 | 3 | 3 | 3 | 3 |
| D604 | | | | | | | | |
| Si [%] | 28.7 | 27.7 | 26.5 | 26.1 | 25.8 | 25.5 | 23.5 | 19.7 |
| Solubility | Y | Y | Y | Y | Y | Y | Y | Y |

TABLE 4

| Ingredient | S9 | S10 | S11 | S12 | S13 | S14 | S15 | S16 |
|---|---|---|---|---|---|---|---|---|
| SiM1 | 75 | 75 | | | | | | |
| SiM2 | | | | | | | | |
| SiM3 | | | | | | | | |
| SiM7 | | | 80 | 80 | 80 | 65 | 65 | 65 |
| SiM11 | | | | | | | | |
| IBXA | | | | | | | 15 | |
| BA | | | | | | | | 15 |
| DCPA | | | | | | 35 | 20 | |
| mxDA | | | | | 20 | | | |
| A-DCP | | | 20 | | | | | |
| PHEDA | 25 | 25 | | 20 | | | | |
| MPDA | | | | | | | | 20 |
| Irgacure 907 | 2 | 2 | 2 | 2 | 2 | 2 | 2 | 2 |
| D810 | 3 | | 3 | 3 | 3 | 3 | 3 | 3 |
| D604 | | 3 | | | | | | |
| Si [%] | 21.3 | 21.3 | 21.2 | 21.2 | 21.2 | 17.2 | 17.2 | 17.2 |
| Solubility | Y | Y | Y | Y | Y | Y | Y | Y |

### Example 2

Photocurable compositions containing as release agent an acetylenic diol as described in Example 1 were investigated with regard to two contact angle measurements: 1) the contact angle to a primed template (CA_{T}), wherein the template was a quartz slide primed with the photocurable composition to be tested; and 2) the contact angle to a substrate (CA_{S}), wherein the substrate was a silicon wafer coated with an adhesion layer coating. The adhesion layer coating was a copolymer made from the mixture of Isorad 501 (Schenectady International, Inc. in Schenectady), see formula 18 above, and hexamethoxymethylmelamine (Cymel 303 from CYTEC, USA). It is desired to have for both CA_{T} and CA_{S} low contact angles, which allows an easy spreading of the photocurable composition, wherein the contact angle to the template shall be larger than the contact angle to the substrate, i.e., CA_{T}>CA_{S}.

A summary of the contact angle measurements for samples S9 and S10 is shown in Table 5. It can be seen that both compositions S9 and S10 had low contact angles to the template and substrate, however the contact angles to the template (CA_{T}) were lower than the contact angles to the substrate (CA_{S}).

The photocurable compositions S9 and S10 were modified in an attempt to tune the contact angles by further adding the fluorine-containing surfactant FS2000M1 in varying amounts (see formula 9). As can be also seen in Table 5, the addition of surfactant FS2000M1 increased the contact angle to the template while it decreased the contact angle to the substrate decreased (see samples S9-1 to S9-4 and S10-1 to S10-4). Accordingly, it was possible by adding of 0.25 wt % FS2000M1, to obtain the desired correlation that the contact angle to the template is greater than the contact angle to the substrate (CA_{T}>CA_{S}). The maximum amount of adding surfactant FS2000M1 was 0.75 wt %, with higher amounts the photocurable compositions were not stable anymore and underwent phase separation, indicated with “NS.”

TABLE 5

| | S9 | S9-1 | S9-2 | S9-3 | S9-4 | S10 | S10-1 | S10-2 | S10-3 | S10-4 |
|---|---|---|---|---|---|---|---|---|---|---|
| D810 | 3 | 3 | 3 | 3 | 3 | 0 | 0 | 0 | 0 | 0 |
| D604 | 0 | 0 | 0 | 0 | 0 | 3 | 3 | 3 | 3 | 3 |
| FS200M1 | 0 | 0.25 | 0.5 | 0.75 | 1 | 0 | 0.25 | 0.5 | 0.75 | 1 |
| CA_{T} | 5.4 | 5.8 | 5.9 | 6.1 | NS | 5.6 | 5.8 | 6.1 | 6.2 | NS |
| CA_{S} | 5.7 | 5.5 | 5.4 | 5.2 | NS | 5.7 | 5.5 | 5.4 | 5.2 | NS |
| Δ CA | −0.3 | 0.3 | 0.5 | 0.9 | | −0.1 | 0.3 | 0.7 | 1 | |

A similar trend of the contact angle measurements could be observed with photocurable compositions S15 and S16. For these measurements, the additional surfactant added next to the acetylenic diol was the fluorine-containing surfactant S554, shown above in formula (7). As shown in Table 6, the contact angles to the template and to the substrate were low for both photocurable compositions, however, when the photocurable compositions contained only acetylenic diol (D810) as release agent the contact angle to the substrate was greater than the contact angle to the template. Adding 0.5 wt % or 1.0 wt % of release agent S554 in addition to the acetylenic diol, the contact angle could be tuned, such that the contact angle to the template was greater than the contact angle to the substrate (CA_{T}>CA_{S}), see samples S15-1, S15-2 and S16-1 and S-16-2.

Adding furthermore as a third release agent 2 wt % of release agent FS2KM2 (a fluorine-free surfactant), see sample S16-3, the contact angles to both the template and the substrate further increased, however, the increase of the contact angle to the template was much larger, and the relationship CA_{T}>CAₛ could be maintained, with a difference of 4.6 degrees.

TABLE 6

| | S15 | S15-1 | S15-2 | S16 | S16-1 | S16-2 | S16-3 |
|---|---|---|---|---|---|---|---|
| D810 | 3 | 3 | 3 | 3 | 3 | 3 | 3 |
| [wt %] | | | | | | | |
| S554 | 0 | 0.5 | 1.0 | 0 | 0.5 | 1.0 | 1 |
| [wt %] | | | | | | | |
| FS2KM2 | 0 | 0 | 0 | 0 | 0 | 0 | 2 |
| [wt %] | | | | | | | |
| CA_{T} [°] | 6.1 | 6.1 | 6.1 | 5.0 | 5.1 | 5.4 | 10.2 |
| CA_{S} [°] | 6.3 | 5.7 | 5.6 | 5.3 | 4.7 | 4.8 | 5.6 |
| Δ CA [°] | −0.2 | 0.4 | 0.5 | −0.3 | 0.4 | 0.6 | 4.6 |

### Measuring of the Contact Angles

The contact angles were measured at room temperature using a Drop master DM-701 contact angle meter (made by Kyowa Interface Science Co. Ltd., Japan). For each contact angle measurement, 2 ml of the test sample was added to the syringe, of which a drop of 2 μl was added by the machine to the target surface. Drop images were continuously captured by a CCD camera from the time the water drop touched the target surface. The contact angle was automatically calculated by software associated with the Drop master DM-701 contact angle meter. The data presented in Tables 5 and 6 are the contact angles at a time of 3 seconds after touching the target surface.

### Viscosities

The viscosities measured for all samples shown in Table 1 show that even the representative samples Si, S2, and S3 have very low viscosities, even below 10 mPa·s.

The viscosities were measured at 23° C., using a Brookfield Viscometer LVDV-II+Pro at 200 rpm, with a spindle size #18. For the viscosity testing, about 6-7 mL of sample liquid was added into the sample chamber, enough to cover the spindle head. For all viscosity testing, at least three measurements were conducted and an average value was calculated.

The viscosities of photocurable compositions S1 to S16 was between 4 mPa·s and 25 mPa·s.

### Testing of the Stability of the Photocurable Compositions:

For testing the stability, the respective photocurable composition was prepared by combining all ingredients in a 8 ml glass vial and stirring the mixture with a Corning® vortex mixer for about 1-2 minutes. Thereafter, the glass vial was closed with a cap and mixing of the sample was continued by placing the glass vial on a roller mixer. The roll mixing was continued until the mixture contained no solids anymore or no liquid phase separation could be observed. After the mixing, the glass vial containing photocurable composition was stored at room temperature on a shelf. The photocurable composition in the glass vial was observed via visual perception every 24 hours regarding the forming of precipitates or liquid phase separation. For evaluating of phase separation, an Energizer flash light was used and positioned on the outer wall of the glass bottle and switched on. If the light beam could pass the bottle without distraction, this was regarded as having a clear solution in the bottle, while diffusion of the light beam by light scattering (Tyndall effect) according to visual perception was used as indication for phase separation, when the sample became instable and not usable anymore. Another clear indication for phase separation (instability) was the visual observance of particles that have been precipitated to the bottom of the vial, or the forming of two liquid layers.

### Silicon Content Calculation

The silicon content of the polymerizable material of the photocurable compositions was calculated according to the following equation: Si [wt %]=[Σwᵢ(nᵢM_{Si})/Mᵢ)]×100%, with M_{Si} being the molecular weight of silicon, Mᵢ being the molecular weight of the respective complete monomer, nᵢ the mol amount of Si in the respective monomer, wᵢ the mol amount of the respective monomer in the complete composition, e.g. wᵢ=0.5 means that the respective monomer contributes to 50 wt % in the composition.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material, a non-fluorine-containing release agent, and a photoinitiator, wherein
the polymerizable material comprises at least one silicon-containing monomer having a structure of formula (1) 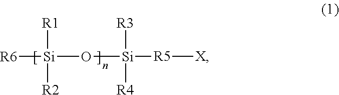
with R1, R2: —O—Si(CH₃)₃, or alkyl, or aryl, or alkylaryl
R3, R4: —O—Si(CH₃)₃, or alkyl, or aryl, or alkylaryl
R5: C₁-C₅-alkyl, or aryl, or alkylaryl
R6: —R5-X, or X, or —O—Si(CH₃)₃, or alkyl, or aryl, or alkylaryl
X: acrylate or methacrylate
n: 0-4;
an amount of silicon (Si) in the photocurable composition is at least 15 wt % based on the total weight of the polymerizable material; and
the non-fluorine-containing release agent includes an acetylenic diol.

2. The photocurable composition of claim 1, wherein the acetylenic diol has a structure of formula (2) or formula (3): 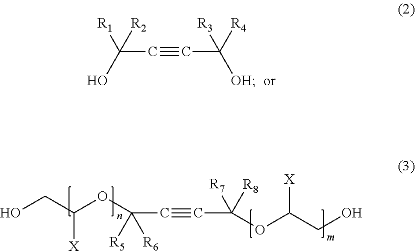
with R1, R3, R5, and R7 being C₁-C₃ alkyl; and R2, R4, R6, and R8 being C₄-C₁₂ alkyl or isoalkyl, X being H or C₁-C₁₀ alkyl, and m, n being 1-40.

3. The photocurable composition of claim 2, wherein the acetylenic diol includes a structure of formula (4):

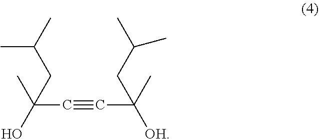 [SMILES: CC(C)CC(C)(O)C#CC(C)(O)CC(C)C]

4. The photocurable composition of claim 2, wherein the acetylenic diol is an ethoxylated acetylenic diol having a structure of formula (5) or (6):

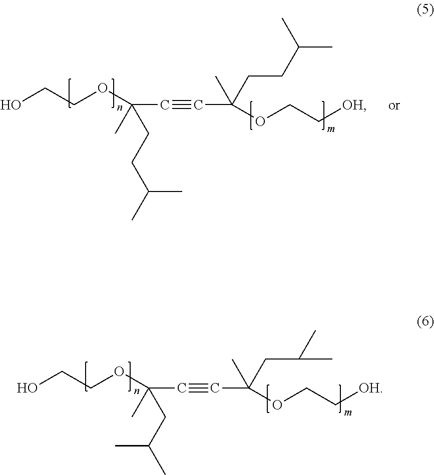

5. The photocurable composition of claim 1, wherein the amount of Si is at least 20 wt % based on the total weight of the photocurable composition.

6. The photocurable composition of claim 1, wherein a molecular weight of the silicon-containing monomer is at least 100 g/mol and not greater than 800 g/mol.

7. The photocurable composition of claim 1, wherein an amount of the at least one silicon-containing monomer is at least 45 wt % based on the total weight of the polymerizable material.

8. The photocurable composition of claim 1, wherein the photocurable composition comprises at least one further release agent which is not an acetylenic diol.

9. The photocurable composition of claim 1, wherein a viscosity of the photocurable composition is not greater than 30 mPa·s.

10. The photocurable composition of claim 1, wherein an amount of the polymerizable material is at least 90 wt % based on the total weight of the photocurable composition.

11. The photocurable composition of claim 1, wherein the at least one silicon-containing monomer includes at least two different silicon-containing monomers.

12. The photocurable composition of claim 1, wherein the at least one silicon-containing monomer is selected from the group of:
methacryloxymethyltris(trimethylsiloxane)silane (SiM1),
1,3-bis(3-methacryloxypropyl)tetrakis(trimethylsiloxy)disiloxane (SiM2)
3-acryloxypropyl-tris(trimethylsiloxy)silane (SiM3),
(methacryloxymethyl)bis(trimethylsiloxy)methylsilane (SiM4),
3-methacryloxypropylbis(trimethylsiloxy)methylsilane (SiM5),
(3-acryloxypropyl)methylbis(trimethylsiloxy)silane (SiM6),
methacryloxypropyltris(trimethylsiloxy)silane (SiM7),
acryloxymethyltrimethylsilane (SiM8),
acryloxymethyltris(trimethylsiloxy)silane (SiM9),
1,3-bis[(acryloxymethyl)phenethyl]tetramethyldisiloxane (SiM10),
methacryloxypropyl terminated polydimethylsiloxane (SiM11),
or any combination thereof.

13. The photocurable composition of claim 1, wherein an amount of the non-fluorine-containing release agent is at least 2 wt %.

14. The photocurable composition of claim 1, wherein a stability factor (SF) of the photocurable composition is at least 14, the stability factor being defined as an amount of days under room temperature wherein the photocurable composition does not show a phase separation.

15. The photocurable composition of claim 1, wherein the polymerizable material further comprises at least one polymerizable monomer not containing silicon.

16. The photocurable composition of claim 15, wherein the polymerizable monomer not containing silicon includes an acrylate monomer.

17. The photocurable composition of claim 16, wherein an amount of the acrylate monomer is at least 20 wt %.

18. A laminate, the laminate comprising a substrate and a photo-cured layer overlying the substrate, wherein the photo-cured layer is formed from the photocurable composition of claim 1.

19. A method of forming a photo-cured layer on a substrate, comprising:
applying a layer of a photocurable composition on the substrate, wherein the photocurable composition comprises a polymerizable material, a non-fluorine-containing release-agent, and at least one photoinitiator, wherein
the polymerizable material comprises at least one silicon-containing monomer having a structure of formula (1) 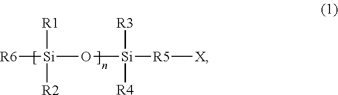
with R1, R2: —O—Si(CH₃)₃, or alkyl, or aryl, or alkylaryl
R3, R4: —O—Si(CH₃)₃, or alkyl, or aryl, or alkylaryl
R5: C₁-C₅-alkyl, or aryl, or alkylaryl
R6: —R5-X, or X, or —O—Si(CH3)3, or alkyl, or aryl, or alkylaryl
X: acrylate or methacrylate
n: 0-4;
an amount of silicon (Si) in the photocurable composition is at least 15 wt % based on the total weight of the polymerizable material; and
the non-fluorine-containing release agent includes an acetylenic diol;
bringing the photocurable composition into contact with a template or a superstrate;
irradiating the photocurable composition with light to form a photo-cured layer; and
removing the template or the superstrate from the photo-cured layer.

20. A method of manufacturing an article, comprising:
applying a layer of a photocurable composition on a substrate, wherein the photocurable composition comprises a polymerizable material, a non-fluorine-containing release agent, and at least one photoinitiator, wherein
the polymerizable material comprises at least one silicon-containing monomer having a structure of formula (1) 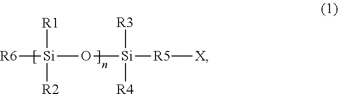
with R1, R2: —O—Si(CH₃)₃, or alkyl, or aryl, or alkylaryl
R3, R4: —O—Si(CH₃)₃, or alkyl, or aryl, or alkylaryl
R5: C₁-C₅-alkyl, or aryl, or alkylaryl
R6: —R5-X, or X, or —O—Si(CH₃)₃, or alkyl, or aryl, or alkylaryl
X: acrylate or methacrylate
n: 0-4;
an amount of silicon (Si) in the photocurable composition is at least 15 wt % based on the total weight of the polymerizable material; and
the non-fluorine-containing release agent release agent includes an acetylenic diol;
bringing the photocurable composition into contact with a template or a superstrate;
irradiating the photocurable composition with light to form a photo-cured layer;
removing the template or the superstrate from the photo-cured layer;
forming a pattern on the substrate;
processing the substrate on which the pattern has been formed in the forming; and
manufacturing an article from the substrate processed in the processing.
